(19) United States
(12) Patent Application Publication
(10) Pub. No.: US 2011/0018602 A1
(43) Pub. Date: Jan. 27, 2011

(54) EDGE-SENSITIVE FEEDBACK-CONTROLLED PULSE GENERATOR

(75) Inventors: Shahid ALI, New Delhi (IN); Sharad Gupta, Bangalore (IN); Kundapur Sujan Manohar, Kundapur (IN)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/508,572

(22) Filed: Jul. 24, 2009

(51) Int. Cl. H03K 3/00

(52) U.S. Cl. 327/230

(57) ABSTRACT

Edge-sensitive Feedback-controlled pulse generator. A circuit includes a pulse generating circuit responsive to a desired transition in an input signal to initiate an output pulse. The circuit also includes a delay circuit responsive to the output pulse to generate a feedback signal. Further, the circuit includes a first latch that renders the pulse generating circuit unresponsive to any change in the input signal until the feedback signal has been generated, a switch responsive to the feedback signal to complete the output pulse, a second latch responsive to a change in the input signal after the feedback signal has been generated to render the pulse generating circuit responsive to a subsequent occurrence of the desired transition in the input signal to initiate the output pulse again, and a third latch responsive to the change in the input signal after the feedback signal has been generated.

### FIELD

Embodiments of the disclosure relate generally to the field of pulse generator and more particularly, to the field of edge-sensitive feedback-controlled pulse generator.

### BACKGROUND

A pulse generator is a circuit that generates a high or low pulse at an output in response to a rising or falling edge at an input. Output-feedback based pulse generators are used quite often as they provide robust pulse generation. An exemplary output-feedback based pulse generator is shown in FIG. 1 (Prior Art). The circuit of FIG. 1 is intended to provide an output pulse of a defined duration in response to a rising edge (positive transition) at an input node 105. When a rising edge is applied to the input node 105, the signal at an output node 110 is driven from a logic level HI to a logic level LO by a circuit 115 between the node 105 and the output node 110. The transition at the output node 110 passes through a resistive-capacitive (RC) feedback path 120 to generate a feedback signal. The feedback signal activates a transistor 125 which activates a transistor 130, causing the output node 110 to be reset back to a logic level HI and resulting in a HI-to-LO-to-HI output pulse with a duration determined by the time constant of components of the RC feedback path 120. The output pulse reset should ideally occur after the feedback signal has been generated. However, if the signal at the input node 105 goes LO before the feedback signal has been generated, the output pulse will be reset to a logic level HI by a transistor 135, resulting in a truncated or distorted output pulse. Further, once signal at the input node 105 goes to a logic level HI, a node 140 is in a high-impedance state for the entire duration of the output pulse. Also, if the voltage at the node 140 discharges, it can cause the output pulse to terminate even before the feedback signal arrives.

In light of the foregoing discussion there is a need for a pulse generator that overcomes one or more of the above-mentioned issues.

### SUMMARY

Embodiments of the disclosure described herein provide a pulse generator and a method for generating a pulse in the pulse generator.

An example of a circuit includes a pulse generating circuit responsive to a desired transition in an input signal to initiate an output pulse. The circuit also includes a delay circuit responsive to the output pulse to generate a feedback signal. Further, the circuit includes a first latch that renders the pulse generating circuit unresponsive to any change in the input signal until the feedback signal has been generated. Furthermore, the circuit includes a switch responsive to the feedback signal to complete the output pulse. In addition, the circuit includes a second latch responsive to a change in the input signal after the feedback signal has been generated to render the pulse generating circuit responsive to a subsequent occurrence of the desired transition in the input signal to initiate the output pulse again. Further, the circuit includes a third latch responsive to the change in the input signal after the feedback signal has been generated to prevent initiation of the output pulse again until the subsequent occurrence of the desired transition in the input signal.

An example of a pulse generator includes a pulse generating circuit responsive to a desired transition in an input signal to initiate an output pulse. The pulse generator also includes a delay circuit responsive to the output pulse to generate a feedback signal. Further, the pulse generator includes a latching circuit that renders generation of the output pulse unresponsive to any change in the input signal until the feedback signal has been generated, completes the output pulse in response to the feedback signal, and prevents another output pulse from being generated until a subsequent occurrence of the desired transition in the input signal.

An example of a method for generating pulses includes initiating an output pulse in response to a desired transition in an input signal. The method also includes latching the output pulse for a predetermined time. Further, the method includes terminating the output pulse when the predetermined time has elapsed. Furthermore, the method includes preventing initiation of another output pulse until a subsequent occurrence of the desired transition in the input signal.

### BRIEF DESCRIPTION OF THE VIEWS OF DRAWINGS

In the accompanying figures, similar reference numerals may refer to identical or functionally similar elements. These reference numerals are used in the detailed description to illustrate various embodiments and to explain various aspects and advantages of the present disclosure.

FIG. 1 is a schematic representation of a pulse generator in accordance with the prior art;

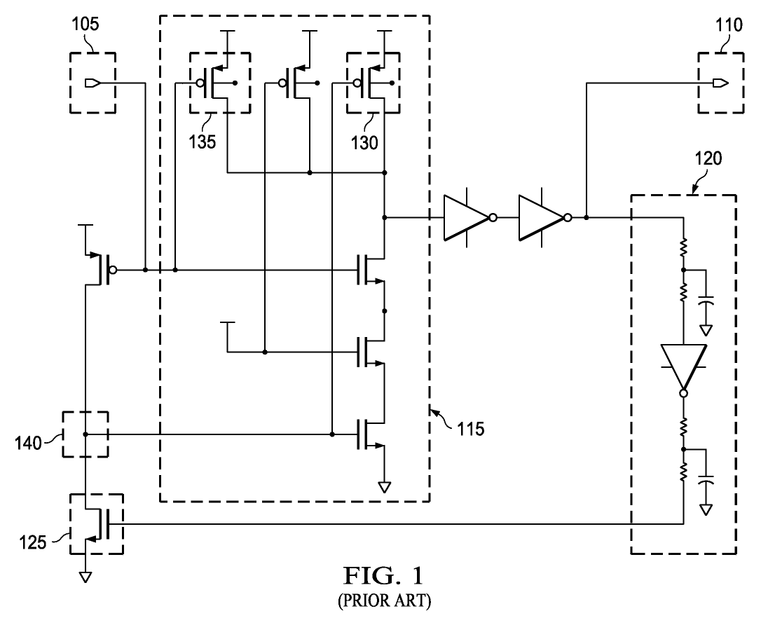

FIG. 2 is a schematic representation of a pulse generator in accordance with one embodiment;

FIG. 3 is a flow chart illustrating a method for generating a pulse in accordance with one embodiment; and

FIG. 4 is a graphical representation of behavior of a pulse generator at power-up and after a transition at input in accordance with one embodiment.

### DETAILED DESCRIPTION OF THE EMBODIMENTS

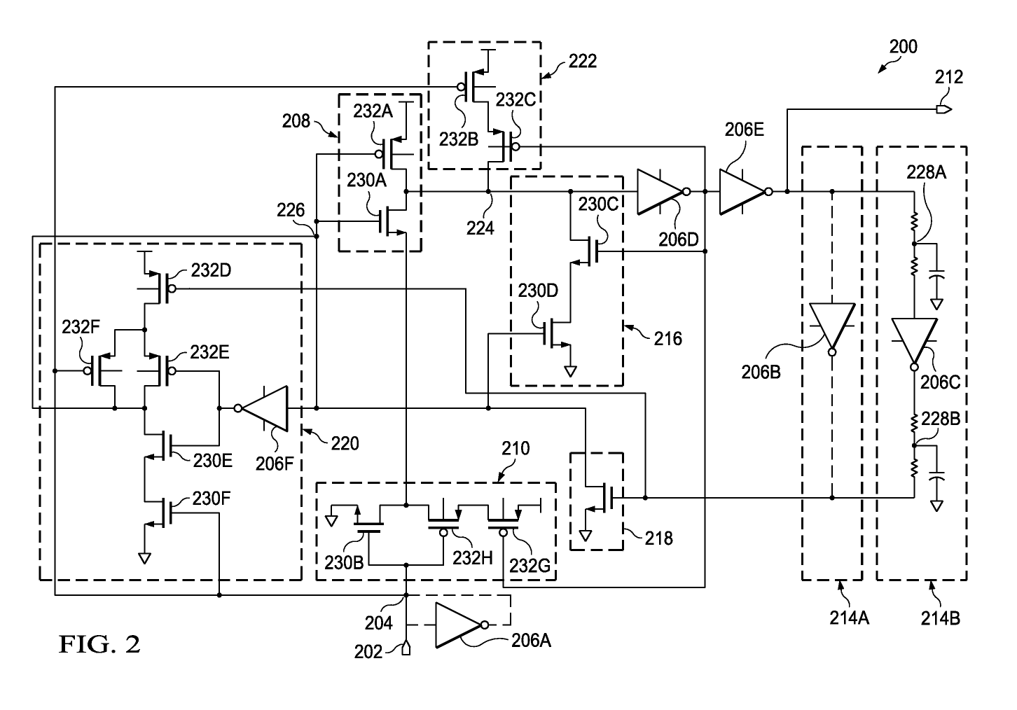

FIG. 2 is a schematic representation of a pulse generator 200 in accordance with one embodiment.

The pulse generator 200 is an output-feedback based pulse generator. The pulse generator 200 includes an input terminal 202 coupled to a node 204. An input signal is received at the input terminal 202 and at the node 204. A desired transition occurs in the input signal and in response to the desired transition a pulse generating circuit initiates an output pulse. The desired transition is a positive transition in which logic level of the input signal shifts from LO to HI for a positive edge triggered pulse generator. The logic level at the node 204 also shifts from LO to HI.

In some embodiments, the input terminal 202 may not be coupled to the node 204 but can be connected to the node 204 through an inverter 206A. The pulse generator 200 then functions as a negative edge triggered pulse generator. The node 204 receives an inverted input signal. A desired transition occurs in the input signal and in response to the desired transition the pulse generating circuit initiates the output pulse. The desired transition is a negative transition in which logic level of the input signal shifts from HI to LO for negative edge triggered pulse generator. The logic level at the node 204 shifts from LO to HI due to the inverter 206A.

The pulse generating circuit includes an inverter circuit 208 and a prevention circuit 210 to initiate an output pulse of a defined duration at an output terminal 212 in response to transition of the logic level at the node 204 from LO to HI. In some embodiments, initially, when the pulse generator 200 is powered up then the logic level at the output terminal 212 is set to a default HI. The output pulse is initiated by driving output at the output terminal 212 from logic level HI to logic level LO. The duration of the output pulse is dictated by a delay circuit, for example a delay circuit 214A or a delay circuit 214B, which is responsive to the output pulse to generate a feedback signal which is time-delayed. A latching circuit includes a first latch 216, hereinafter referred to as latch 216, that prevents floating nodes and renders generation of the output pulse unresponsive to any change in the input signal until the feedback signal has been generated. The latching circuit also includes a switch 218 responsive to the feedback signal to transition the logic level of the output pulse to HI and thereby complete the output pulse. A second latch 220, hereinafter referred to as latch 220, of the latching circuit latches the output to logic level HI until the input signal changes (“changes” as used in this context refers to a change in logic level at the node 204 from HI to LO) after the feedback signal has been generated. The latch 220 is responsive to the change in the input signal to render the pulse generating circuit responsive to a subsequent occurrence of the desired transition in the input signal to initiate the output pulse again. A third latch 222, hereinafter referred to as latch 222 of the latching circuit retains the output at logic level HI when the change occurs in the input signal after the feedback signal has been generated and thereby prevents generation of another output pulse until the subsequent occurrence of the desired transition in the input signal. The latch 222 also prevents floating nodes.

In some embodiments, a negative metal oxide semiconductor (NMOS) transistor can be used as the switch 218.

Initially when the pulse generator 200 is powered up then the node 204 is at logic level LO, a node 224 and a node 226 are set to a default logic level HI. The desired transition then occurs in the input signal and the logic level at the node 204 shifts from LO to HI. The node 224 discharges through an NMOS transistor 230A of the inverter circuit 208 and an NMOS transistor 230B of the prevention circuit 210 to the logic level LO resulting in transition of the output at the output terminal 212 from logic level HI to logic level LO, thereby initiating the output pulse at logic level LO. The signal initiated at the node 224 is delayed by a plurality of inverters, for example an inverter 206D and an inverter 206E, to obtain the output at the output terminal 212. The delay circuit 214A or the delay circuit 214B, whichever has been included in a particular device, generates the feedback signal. The feedback signal is time delayed and is generated in response to the initiation of the output pulse.

The signal at the node 204 can fall to logic level LO before the feedback signal is generated. Such a situation is referred to as input state change which occurs when the input signal has very short pulse width. The output pulse and the signal at the node 224 are latched to logic level LO by an NMOS transistor 230C and an NMOS transistor 230D of the latch 216, which are active to prevent any change in the output pulse due to the input state change and to prevent floating state of the signal at the node 224. The feedback signal is then generated at logic level HI. The feedback signal activates the switch 218 which in turn pushes the signal at the node 226 to level LO. A positive metal oxide semiconductor (PMOS) transistor 232A of the inverter circuit 208 is active charging the node 224 and pulling the signal at the node 224 to logic level HI. The output pulse transitions to logic level HI. The transition completes and terminates the output pulse.

After the feedback signal is generated the signal at the node 204 can continue to be at logic level HI for a long time. Such a situation is referred to as high leakage corner. The feedback signal is then generated at logic level LO. The feedback signal inactivates the switch 218. The signal at the node 226 is maintained at logic level LO by an inverter 206F, an NMOS transistor 230E and an NMOS transistor 230F of the latch 220. The NMOS transistor 230E and the NMOS transistor 230F are active. The PMOS transistor 232A of the inverter circuit is active which maintains the signal at the node 224 and the output at the output terminal 212 at logic level HI.

After the feedback signal is generated the signal at the node 204 can fall to logic level LO. When the signal at the node 204 falls to logic level LO then a PMOS transistor 232B and a PMOS transistor 232C of the latch 222 are active resulting in retaining the signal at the node 224 and the output at output terminal 212 at logic level HI, and preventing any further output pulse from being generated until the signal at the node 204 transitions to logic level HI again. The latch 222 also prevents floating state of the signal at the node 224. A PMOS transistor 232D, a PMOS transistor 232E and a PMOS transistor 232F of the latch 220 are active to pull the signal at the node 226 to logic level HI. The logic level HI of the signal at the node 226 activates the NMOS transistor 230A and thereby renders the NMOS transistor 230B to initiate another output pulse in response to a subsequent occurrence of the desired transition in the input signal. The NMOS transistor 230B is cutoff, and a PMOS transistor 232G and a PMOS transistor 232H of the prevention circuit 210 are active to prevent floating state of the signal at the drain of the NMOS transistor 230B.

The inverter circuit 208 includes the PMOS transistor 232A with source connected to positive supply terminal, gate connected to the node 226, and drain connected to the node 224, and the NMOS transistor 230A with source connected to drain of the NMOS transistor 230B, gate connected to the node 226 and drain connected to the node 224 and to the drain of the PMOS transistor 232A. Output of the inverter circuit 208 is obtained at the node 224 and is indicative of the output at the output terminal 212. The inverter circuit is driven by logic level of a signal at the node 226. The prevention circuit 210 also includes a plurality of metal oxide semiconductor (MOS) transistors, for example the NMOS transistor 230B having source connected to negative supply terminal, gate connected to the node 204, and drain connected to the drain of the PMOS transistor 232H; the PMOS transistor 232H having gate connected to the node 204, and source connected to the drain of the PMOS transistor 232G; and the PMOS transistor 232G having source connected to positive supply terminal and gate connected to an output of the inverter 206D. Each latch includes a plurality of MOS transistors. In some embodiments, the latch 216 and the latch 222 are half latches and the latch 220 is a full latch.

The latch 216 includes the NMOS transistor 230C having drain connected to the node 224, gate connected to the output of the inverter 206D, and source connected to the drain of the NMOS transistor 230D; and the NMOS transistor 230D having gate connected to the switch 218, and the source connected to negative supply terminal. The latch 222 includes the PMOS transistor 232B having source connected to positive supply terminal, gate connected to the node 204 and drain connected to the source of the PMOS transistor 232C; and the PMOS transistor 232C having gate connected to the output of the inverter 206D, and drain connected to the node 224.

The latch 220 includes the PMOS transistor 232D having source connected to positive supply terminal, gate connected to the output of any one of the delay circuit 214A or the delay circuit 214B, and drain connected to the source of the PMOS transistor 232E and to the source of the PMOS transistor 232F; the PMOS transistor 232E having drain connected to the node 226, and gate connected to the output of the inverter 206F; the PMOS transistor 232F having gate connected to the node 204, and drain connected to the node 226; the NMOS transistor 230E having gate connected to the output of the inverter 206F, drain connected to the node 226 and source connected to the drain of the NMOS transistor 230F; the NMOS transistor 230F having gate connected to the node 204, source connected to negative supply terminal; and the inverter 206F with input lead connected to the switch 218.

Any one of the delay circuit 214A or the delay circuit 214B can be used. For example, an inverter 206B of the delay circuit 214A or more such inverters can be used for generating time delay in case of pulse generators for pulse flops. The inverter 206B has one lead connected to the output terminal 212 and another lead connected to the gate of the switch 218. One or more resistive capacitive (RC) circuits, for example a RC circuit 228A and a RC circuit 228B can be used in combination with an inverter 206C of the delay circuit 214B or more inverters in case of pulse generators for memories and core flops. The RC circuit 228A has one lead connected to the output terminal 212 and the RC circuit 228B has one lead connected to the gate of the switch 218. Other leads of the RC circuit 228A and the RC circuit 228B are connected to the inverter 206C.

The pulse generator 200 functions as a positive edge triggered pulse generator. When the inverter 206A is coupled to the input terminal 202 then the pulse generator 200 functions as a negative edge triggered pulse generator. The pulse generator 200 provides a negative going output pulse in response to a positive going pulse at the node 204. It is apparent that the output pulse can be inverted by connecting an inverter in series with the output terminal 212 to obtain positive going output pulse. The positive going output pulse can also be obtained by reconfiguring the pulse generator 200. The pulse generator 200 can be reconfigured by replacing the NMOS transistors in FIG. 2 by PMOS transistors, replacing the PMOS transistors in FIG. 2 by NMOS transistors, replacing the positive supply terminals by the negative supply terminals, and replacing the negative supply terminals by the positive supply terminals. The functioning of the reconfigured pulse generator remains similar to the pulse generator 200. The reconfigured pulse generator functions as a negative edge triggered pulse generator. When an inverter is connected in series with the input terminal then the reconfigured pulse generator can function as a positive edge triggered pulse generator. The reconfigured pulse generator provides a positive going output pulse in response to a negative going pulse at the node 204. The output pulse of the reconfigured pulse generator can be inverted by connecting an inverter in series with the output terminal 212 to obtain negative going output pulse.

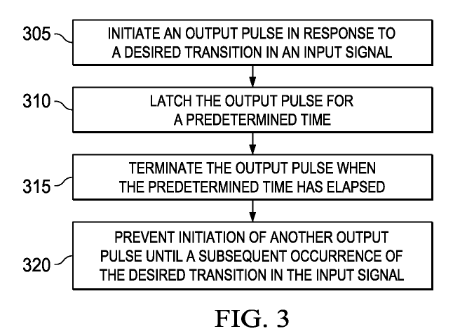

FIG. 3 is a flow chart illustrating a method for generating a pulse in accordance with one embodiment.

A pulse generator can be used for generating a positive going output pulse or a negative going output pulse, in response to a rise or fall in the input signal. The pulse generators are used for self timed applications, for example memories, pulse-flops, and address transition detection (ATD) circuits.

At step 305, an output pulse is initiated in response to a desired transition in the input signal of the pulse generator. The desired transition is defined as a positive transition (LO to HI) for a positive edge triggered pulse generator and as a negative transition (HI to LO) for a negative edge triggered pulse generator. The input signal can be fed from an external source, for example an analog to digital converter.

At step 310, the output pulse is latched for a predetermined time. The predetermined time is equivalent to time taken for generating a feedback signal. A delay circuit can be used for generating the feedback signal and dictating duration of the output pulse. In some embodiments, the output pulse can be latched using a half latch, for example a combination of MOS transistors. The latching of the output pulse prevents resetting of the output in case the input signal changes before the feedback signal has been generated.

At step 315, the output pulse is terminated when the predetermined time has elapsed. The output pulse can be terminated using, for example, a switch.

At step 320, initiation of another output pulse is prevented until a subsequent occurrence of the desired transition in the input signal. The initiation can be prevented by latching the output after the output pulse is terminated. The latching prevents any change in the output when any transition other than desired transition occurs in the input signal.

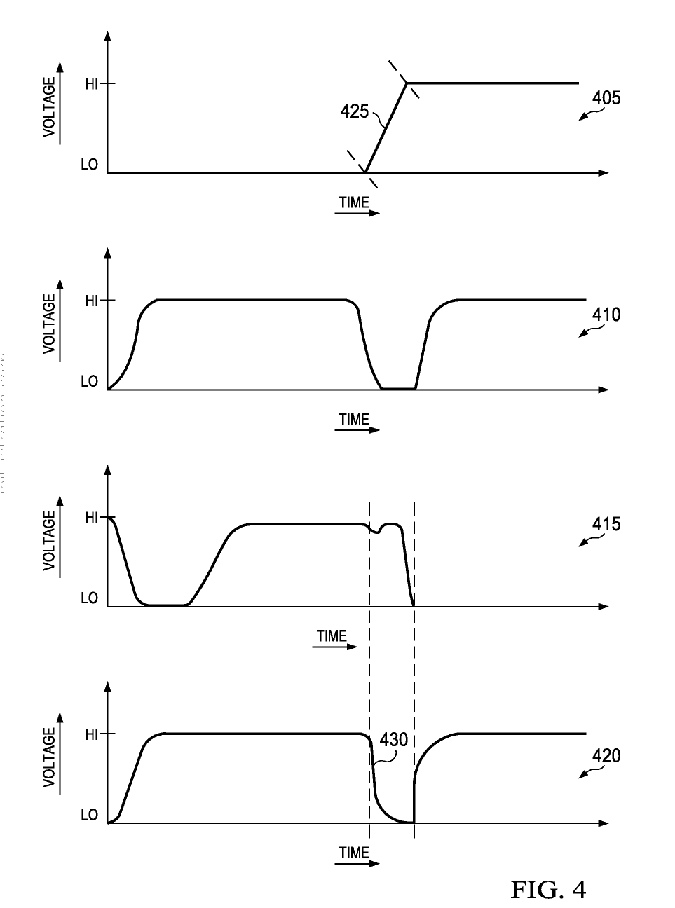

FIG. 4 is a graphical representation of behavior of a pulse generator 200 at power-up and after a transition at input in accordance with one embodiment.

The graphical representation includes a waveform 405 corresponding to a signal at the node 204, a waveform 410 corresponding to a signal at the node 224, a waveform 415 corresponding to a signal at the node 226, and a waveform 420 corresponding to output at the output terminal 212.

Initially at power-up, logic level of the signal at the node 204 is LO. The pulse generator 200 is capable of resolving itself after power-up to settle various nodes at default states. For example, logic level of the signal at the node 224 and logic level of the signal at the node 226 are set to default HI. A transition (425) then occurs in the signal at the node 204. The transition (425) can occur in response to a positive going pulse (desired transition) in the input signal if the pulse generator 200 is a positive edge triggered or in response to a negative going pulse (desired transition) in the input signal if the pulse generator 200 is a negative edge triggered. The output pulse (430) is initiated in response to the transition (425). The output pulse (430) terminates upon generation of a feedback signal which drives the signal at the node 226 (waveform 415) to a logic level LO. The output at the output terminal is maintained at logic level HI until subsequent occurrence of the transition (425).

In the foregoing discussion, the term “coupled” refers to either a direct electrical connection between the devices connected or an indirect connection through one or more passive or active intermediary devices. The term “circuit” means at least either a single component or a multiplicity of components, either active or passive, that are connected together to provide a desired function. The term “signal” means at least one current, voltage, charge, data, or other signal.

Those skilled in the art will recognize that a wide variety of modifications, alterations, and combinations can be made with respect to the above described embodiments without departing from the scope of the present disclosure, and that such modifications, alterations, and combinations are to be viewed as being within the ambit of the present disclosure.

What is claimed is:

1. A circuit comprising:
a pulse generating circuit responsive to a desired transition in an input signal to initiate an output pulse;
a delay circuit responsive to the output pulse to generate a feedback signal;
a first latch that renders the pulse generating circuit unresponsive to any change in the input signal until the feedback signal has been generated;
a switch responsive to the feedback signal to complete the output pulse;
a second latch responsive to a change in the input signal after the feedback signal has been generated to render the pulse generating circuit responsive to a subsequent occurrence of the desired transition in the input signal to initiate the output pulse again; and
a third latch responsive to the change in the input signal after the feedback signal has been generated to prevent initiation of the output pulse again until the subsequent occurrence of the desired transition in the input signal.

2. The circuit of claim 1, wherein the pulse generating circuit comprises:
an inverter circuit; and
a prevention circuit coupled to the inverter circuit, the prevention circuit preventing floating nodes.

3. The circuit of claim 2, wherein the prevention circuit comprises:
a plurality of metal oxide semiconductor (MOS) transistors.

4. The circuit of claim 1, wherein the delay circuit comprises:
an inverter.

5. The circuit of claim 4, wherein the delay circuit further comprises:
one or more resistive-capacitive (RC) delay circuits.

6. A circuit of claim 1, wherein each latch comprises:
a plurality of metal oxide semiconductor (MOS) transistors.

7. The circuit of claim 6, wherein the second latch further comprises:
an inverter.

8. The circuit of claim 1 wherein the switch comprises:
a metal oxide semiconductor transistor.

9. The circuit of claim 1 further comprising:
an inverter.

10. The circuit of claim 1, wherein the desired transition is one of:
a positive transition; and
a negative transition.

11. A pulse generator comprising:
a pulse generating circuit responsive to a desired transition in an input signal to initiate an output pulse;
a delay circuit responsive to the output pulse to generate a feedback signal; and
a latching circuit that
renders generation of the output pulse unresponsive to any change in the input signal until the feedback signal has been generated,
completes the output pulse in response to the feedback signal, and
prevents another output pulse from being generated until a subsequent occurrence of the desired transition in the input signal.

12. The circuit of claim 11, wherein the pulse generating circuit comprises:
an inverter circuit; and
a prevention circuit coupled to the inverter circuit, the prevention circuit preventing floating nodes.

13. The circuit of claim 11, wherein the latching circuit comprises:
a first latch that renders generation of the output pulse unresponsive to any change in the input signal until the feedback signal has been generated;
a switch responsive to the feedback signal to complete the output pulse;
a second latch responsive to a change in the input signal after the feedback signal has been generated to render the pulse generating circuit responsive to the subsequent occurrence of the desired transition in the input signal to initiate another output pulse; and
a third latch responsive to the change in the input signal after the feedback signal has been generated to prevent initiation of another output pulse until the subsequent occurrence of the desired transition in the input signal.

14. The circuit of claim 13, wherein each latch comprises:
a plurality of metal oxide semiconductor transistors.

15. The circuit of claim 11 further comprising:
an inverter.

16. A method for generating a pulse, the method comprising:
initiating an output pulse in response to a desired transition in an input signal;
latching the output pulse for a predetermined time;
terminating the output pulse when the predetermined time has elapsed; and
preventing initiation of another output pulse until a subsequent occurrence of the desired transition in the input signal.

17. The method of claim 16, wherein the latching comprises:
generating a feedback signal with a delay equivalent to the predetermined time.
